(19) United States
(12) Patent Application Publication
(10) Pub. No.: US 2005/0074985 A1
(43) Pub. Date: Apr. 7, 2005

(54) Method of making a vertical electronic device

(76) Inventor: Woo Sik Yoo, Palo Alto, CA (US)

Correspondence Address: Theodore P. Lopez;MacPHERSON KWOK CHEN & HEID LLP, Suite 226, 1762 Technology Drive, San Jose, CA, 95110, US

(21) Appl. No.: 10/677,616

(22) Filed: Oct. 1, 2003

(51) Int. Cl. H01L 21/332; H01L 21/42; H01L 21/26; H01L 21/477

(52) U.S. Cl. 438/795; 438/530; 438/138

(57) ABSTRACT

A semiconductor substrate having had a semiconductor device formed on the front side of the semiconductor substrate is subjected to an ion implant on the back side of the semiconductor substrate. The active surface of the doped back side is controllably heated to perform an implant anneal. The implant anneal of the back side of the semiconductor substrate is performed using a flash anneal process which avoids causing the destruction of the semiconductor device formed on the front side of the semiconductor substrate.

### BACKGROUND OF THE INVENTION

1. Field of the Invention

This invention generally relates to semiconductor manufacturing equipment and, more particularly, to an apparatus and method for processing of a semiconductor wafer.

2. Related Art

The process of making a typical semiconductor device begins with providing a bulk material, such as Si, Ge, and GaAs in the form of a semiconductor substrate or wafer. Dopants are then introduced into the substrate to create p- and n-type regions. The dopants can be introduced using thermal diffusion or ion implantation methods. In the latter method, the implanted ions will initially be distributed interstitially. Thus, to render the doped regions electrically active as donors or acceptors, the ions must be introduced into substitutional lattice sites. This “activation” process is accomplished by heating the bulk wafer, generally in the range of between 600° C. to 1000° C. When using a silicon wafer, for example, a silicon oxide layer can be “grown” or deposited to provide an electrical interface. Finally a metallization, such as aluminum, is applied using, for example, either evaporation or sputtering technique.

Unfortunately, for reasons related to bulk wafer handling, the bulk wafers must be made thick in order that the wafers can be manipulated during processing. It is known that the greater the thickness of the bulk wafer, the greater are the power consumption, the resistance, and the effort to remove heat.

The ability to implant anneal the back side of the device would require bulk heating of the entire device in excess of 600° C., which is typically above the melting temperature of the metallization layer. Thus, any further heat treatment after the formation of the semiconductor device can cause the destruction of the device.

What is needed is a method and apparatus for making a thin planar semiconductor device capable of supporting back side device formation.

### SUMMARY

The present invention provides an apparatus and associated method for producing vertical semiconductor devices on the front and back side of a substrate. Before formation of semiconductor devices, the present invention provides for doping the front or back side of the semiconductor substrate and controllably heating the active surface of the doped substrate to perform an implant anneal.

In one aspect of the invention, once a semiconductor device has been formed on the front side of the semiconductor substrate, the present invention provides for doping the back side of the semiconductor substrate and controllably heating the active surface of the doped back side to perform an implant anneal. Advantageously, as described in greater detail below, the implant anneal of the back side of the semiconductor substrate is performed without causing the destruction of the semiconductor device already formed on the front side of the semiconductor substrate.

The implant anneal may be accomplished using an energy source, which provides the resultant energy output, as seen by the semiconductor substrate, substantially free of non-uniformities. Beneficially, the resultant energy can be uniformly disposed over the back side substrate surface to heat only the active layer of the back side surface. Because the resultant energy is uniform over the diameter of the substrate there is no significant heating overlap.

In accordance with the present invention the resultant energy can be provided at a very high intensity such that only a short exposure time is necessary to heat the active layer of the substrate. Thus, the process can be referred to as a “flash” anneal process. The flash anneal process, can include crystallizing the active layer of the substrate, implant annealing the active layer, or otherwise heat treating the active layer, such as shallow junction, ultra shallow junction, and source drain anneal.

In one aspect of the invention, a method is provided for forming an electronic device, which includes providing a substrate having a front side and a back side, where the front side has a first semiconductor device disposed thereon. Substrate material is removed from the back side of the substrate to create a substrate of a desired thickness. An impurity is implanted into the back side of the substrate. The back side of the substrate is flashed with radiation energy which impinges on a surface of the back side of the substrate for a substantially instantaneous time to heat an active layer of the substrate to an annealing temperature. A second semiconductor device is formed on the back side of the substrate.

In yet another aspect of the invention, an apparatus for forming an electronic device is provided which includes means for exposing a first surface of a substrate with radiation energy which impinges on the first surface for a substantially instantaneous time to heat an active layer of the substrate to an annealing temperature. The substrate has a second surface which has a semiconductor device formed thereon.

Since, typical annealing processes generally heat the entire bulk substrate, the active layer heating of the present invention allows for heating of a back side of a substrate while avoiding causing the destruction of any metal layers or low melting point layers disposed on the front side surface.

The bulk of the semiconductor wafer need not be heated during the heating process, unless desired, thus, the amount of power used by the apparatus can be significantly reduced. In one embodiment, the power consumed may be less than 10 kWh/wafer, for example, less than about 0.5 kWh/wafer. Similarly, processing times may be reduced since only the active surface of the wafer is being heated.

These and other features and advantages of the present invention will be more readily apparent from the detailed description of the embodiments set forth below taken in conjunction with the accompanying drawings.

### BRIEF DESCRIPTION OF THE FIGURES

FIG. 1 is a schematic illustration of a side view of one embodiment of a semiconductor wafer processing system that establishes a representative environment of the present invention;

FIG. 2A is a simplified illustration of a reactor system in accordance with the principles of the present invention;

FIG. 2B is a simplified illustration of a reactor system in accordance with an alternative embodiment of the present invention;

FIG. 2C is a simplified illustration of a reactor system in accordance with an alternative embodiment of the present invention;

FIG. 2D is a simplified illustration of the active layer of a semiconductor wafer in accordance with principles of the present invention;

FIG. 3 is a simplified illustration of an embodiment of a radiation chamber in accordance with the present invention;

FIG. 4 is a simplified illustration of another embodiment of the present invention;

FIGS. 5A and 5B are simplified illustrations of an embodiment of a flash anneal apparatus in accordance with the present invention;

FIG. 6 is a simplified illustration of a flash anneal apparatus using the reflector assembly of FIGS. 5A and 5B in accordance with the present invention;

FIG. 7 is a simplified illustration of an alternative embodiment of the reflector assembly of FIG. 6 in accordance with the present invention;

FIG. 8 is a simplified illustration of an alternative embodiment of the reflector assembly of FIG. 6 in accordance with the present invention;

FIGS. 9A-9D are simplified circuit diagrams of a power supply to ignite a lamp in accordance with an embodiment of the present invention;

FIG. 10 is an embodiment of a power supply circuit in accordance with the principles of the present invention;

FIG. 11 is an embodiment of a power supply circuit in accordance with the principles of the present invention;

FIGS. 12A-12E are simplified illustrations of the formation of a vertical planar semiconductor device in accordance with an embodiment of the present invention;

FIGS. 13A and 13B are illustrations of wafer temperature profile in accordance with an embodiment of the present invention; and

FIG. 14 is an illustration comparing surface heating by flash at room temperature in accordance with an embodiment of the present invention to a bulk heating anneal.

### DETAILED DESCRIPTION

As used herein, the word “flash” includes it ordinary meaning as generally understood by those of ordinary skill in the art. This definition of flash also includes to give off light suddenly or substantially instantaneous (or in transient bursts) for a duration of time between about 1 nanosecond and about 10 seconds.

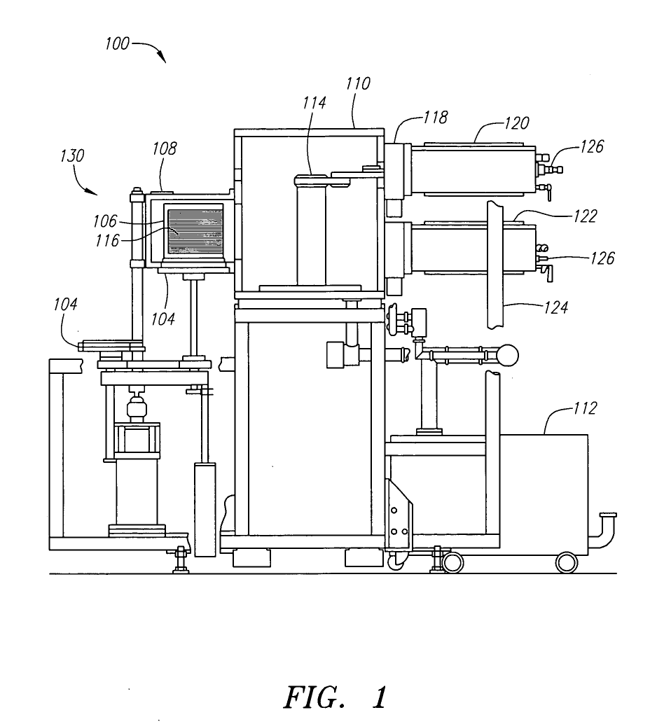

FIG. 1 is a schematic illustration of a side view of one embodiment of a semiconductor wafer processing system 100 that establishes a representative environment of the present invention. Processing system 100 includes a loading station 130 which has multiple platforms 104 for supporting and moving a wafer cassette 106 up and into a loadlock 108. Wafer cassette 106 may be a removable cassette which is loaded into a platform 104, either manually or with automated guided vehicles (AGV). Wafer cassette 106 may also be a fixed cassette, in which case wafers are loaded onto cassette 106 using conventional atmospheric robots or loaders (not shown). Once wafer cassette 106 is inside loadlock 108, loadlock 108 and transfer chamber 110 are maintained at atmospheric pressure or else are pumped down to vacuum pressure using a pump 112. A robot 114 within transfer chamber 110 rotates toward loadlock 108 and picks up a wafer 116 from cassette 106. A reactor or thermal processing chamber 120, which may also be at atmospheric pressure or under vacuum, accepts wafer 116 from robot 114 through a gate valve 118. Optionally, additional reactors may be added to the system, for example reactor 122. Robot 114 then retracts and, subsequently, gate valve 118 closes to begin the processing of wafer 116. After wafer 116 is processed, gate valve 118 opens to allow robot 114 to remove and place wafer 116. Optionally, a cooling station is provided, which allows the newly processed wafers, which may have temperatures upwards of 100° C., to cool before they are placed back into a wafer cassette in loadlock 108.

A representative processing system is disclosed in U.S. Pat. No. 6,410,455, which is herein incorporated by reference for all purposes.

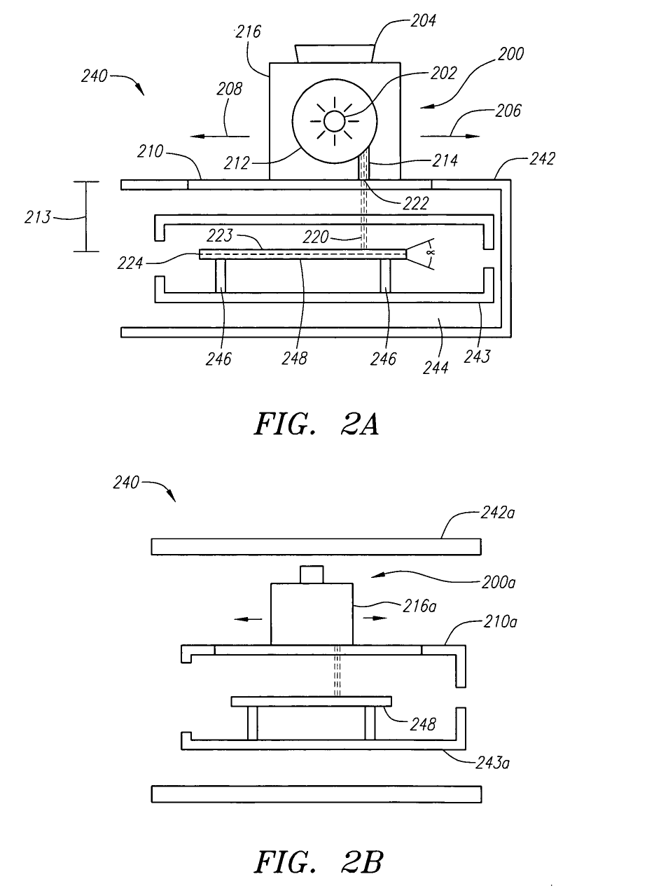

FIG. 2A is a simplified illustration of an embodiment of RTP reactor system 240 in accordance with the principles of the present invention. In this embodiment, reactor system 240 includes a process chamber 242 and a scanner assembly 200. Scanner assembly 200 may be positioned proximate to process chamber 242, such that in operation, the scanner assembly can be made to adequately scan the wafer disposed in the chamber.

In one embodiment, process chamber 242 may include a closed-end tube 243, defining an interior cavity 244. Within tube 243 are wafer support posts 246, typically three (of which two are shown), to support a single wafer 248.

An opening or aperture (not shown) on one end of tube 243, provides access for the loading and unloading of wafer 248 before and after processing. The aperture may be a relatively small opening, but large enough to accommodate the wafer of interest. Having a relatively small aperture size helps to reduce radiation heat loss from tube 243. In one embodiment, the aperture can be made to receive a wafer of between about 0.5 to 0.8 mm thick and up to 300 mm (˜12 in.) in diameter, and the arm and end effector of robot 22. In this embodiment, the aperture is no greater than between about 18 mm and 22 mm, for example, about 20 mm.

Because wafer 248 is loaded and un-loaded using robot 22, tube 243 requires no internal moving parts to position wafer 248, such as lift pins, actuators, and the like. Thus, tube 243 may be constructed with a minimal internal volume-surrounding wafer 248. In one embodiment, the volume of interior cavity 104 is usually no greater than about 1 m³, for example, the volume is no greater than about 0.3 m³. Accordingly, the small tube volume allows reactor system 240 to be made smaller, and as a result, system 10 may be made smaller, requiring less floor space. In one embodiment, tube 243 is made of a transparent quartz or similar material.

FIG. 2A also illustrates scanner assembly 200, which may be used in conjunction with a radiation energy source 202, to provide rapid thermal processing of semiconductor wafer 248. Scanner assembly 200 includes a housing 216 which supports an actuator 204, a reflecting chamber 212, and a radiation outlet channel 214. The external dimensions of housing 216 are determined by the application. For example, the length of housing 216 may be at least as great as, or greater than the diameter of wafer 248.

Actuator 204 provides a conventional means for making scanner assembly 200 operable to scan wafer 248. Actuator 204 may be configured to provide a back and forth scanning motion, as indicated in FIG. 2A by arrows 206 and 208, along a scanning length of tube 243. Actuator 204 may include, but is not limited to, conventional drivers and motion translation mechanisms, such as linear motors, stepper motors, hydraulic drives, and the like, and gears, pulleys, chains, and the like.

In the embodiment shown in FIG. 2A, scanner assembly 200 may be mounted external to both process chamber 242 and tube 243. Scanner assembly 200 is positioned above an optical window 210, which is provided along the scanning length of chamber 242 (i.e. at least as great as the diameter of wafer 248) to allow the radiation energy emitted from housing 216 to enter tube 243 and impinge on wafer 248. In an alternative embodiment shown in FIG. 2B, the scanning motion of scanner assembly 200a may take place internal to process chamber 242a, but external to tube 243a. Scanner assembly 200a is positioned above optical window 210a, formed on tube 243a along the scanning length (i.e. at least as great as the diameter of wafer 248) to allow the radiation energy emitted from housing 216a to enter tube 243a and impinge on wafer 248.

In yet another embodiment, shown in FIG. 2C, scanner assembly 200b may be mounted external to process chamber 242b, with no process tube. In this embodiment, scanner assembly 200b is positioned above optical window 210b, which is provided along the scanning length of chamber 242b (i.e. at least as great as the diameter of wafer 248) to allow the radiation energy emitted from housing 216b to impinge on wafer 248.

Optical window 210 (or 210a) may be made of any material that allows for the transmission of the radiation energy, for example, quartz. Window 210 may have a thickness of between about 1 mm and about 5 mm and a diameter that is at least as great as or greater than wafer 248.

Whether the scanner assembly is positioned inside or outside of the tube, the distance between the surface of the wafer and the scanner assembly, indicated in FIG. 2A as gap 213, should be no greater than about 50 mm, for example, between about 10 mm and 25 mm. The relatively small gap 213 ensures that adequate control of the temperature/radiation energy distribution across wafer 248 is maintainable. A larger gap 213 may cause some of the radiation energy to escape before it impinges on wafer 248.

As further illustrated in FIG. 2A, reflective chamber 212 and radiation outlet channel 214 are disposed within housing 216. Radiation source 202 is disposed within reflective chamber 212, typically positioned such that substantially all of the broadband radiation is allowed to impinge on an internal surface 218 of the chamber. In one embodiment, radiation energy source 202 may be a high-intensity lamp of the type conventionally used in lamp heating operations. In one embodiment, radiation energy source 202 is a filament-less lamp, such as a Xe arc lamp. Typical, power requirements for lamp 202 of the present invention are between about 500 Watts and about 50 kWatts.

The energy emitted from lamp 202 impinges inner surface 218 of chamber 212, which is highly reflective of certain wavelengths and absorptive or non-reflective of others. In one embodiment, surface 218 is coated with a material, which has the reflecting/absorbing characteristic. For example, surface 218 may be coated with gold or silver, where the silver is further coated with a protection coating, such as SiN or any transparent coating, which prohibits oxidation of the silver. In one embodiment, the coating efficiently reflects wavelengths of less than 900 nm, to produce an average wavelength of between about 900 nm and about 200 nm.

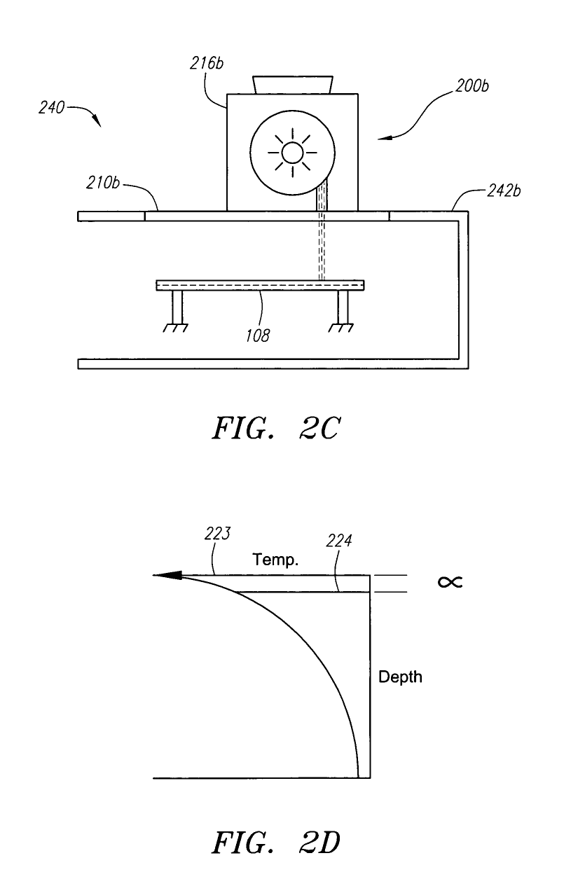

Chamber 212, which may be formed into any suitable geometric shape. For example, as shown in FIG. 2A, chamber 212 may be a round chamber. In a round chamber 212 light energy can be focused at the center of chamber 212 and directed toward radiation outlet channel 214, described below. In this example, radiation energy source 202 can be off-center in chamber 212 to ensure that the focused light energy does not over heat energy source 202. FIG. 3 shows an alternative example of chamber 212, which may be formed into an elliptical chamber. Elliptical chamber 212 can have two focal points. Energy source 202 can be positioned at a first focal point 203, such that the light energy is focused at the second focal point 205 and directed to radiation outlet channel 214.

Referring again to FIG. 2A, the narrow-band energy escapes from chamber 212 through radiation outlet channel 214. Radiation outlet channel 214 can be about 5 mm to 20 mm long; for example, about 10 mm long, to adequately direct the radiation energy along the desired path. Radiation outlet channel 214 has an opening or slit 222 formed on the end of the channel which allows a beam 220 of the radiation energy to escape housing 216. Slit 222 is designed to shape beam 220 as desired, such that an optimal amount of energy may be focused on wafer 248. In one embodiment, slit 222 may be a rectangular opening, which extends the length of scanner assembly 200, and is as great as or greater than the diameter of wafer 248. The size of the opening should be small enough to minimize the amount of energy, which will naturally disperse at the slit opening. Thus, slit 222 may have a width of between about 1 mm and 10 mm; for example, 2 mm. As beam 222 is scanned over wafer 248, a uniform temperature distribution is created across the surface of wafer 248, which heats an active layer 224 of the wafer.

Referring now to FIGS. 2A and 2D, active layer or device layer 224 is a portion of wafer 248, which extends from surface 223 of wafer 248 down to a depth α below surface 223. The depth α is typically between about 0.05 μm and 1 mm, but will vary with the process and device feature size. Active layer 224 is well known in the semiconductor manufacturing industry as that portion of the wafer in which semiconductor devices are formed, such as transistors, diodes, resistors, and capacitors.

It should be understood that the temperature to which active layer 224 is heated is a function of the relationship between the speed at which scanner assembly 200 is moved across wafer 248 and the power supplied to lamp 202. In an exemplary embodiment, the temperature of active layer 224 may range from between about 500° C. to about 1200° C. To achieve these temperatures, the scan rate may vary between about 1 mm/sec to about 100 mm/sec at 500 watts to 50 kwatts. The slower the scan rate, the less power is required. In one embodiment, wafer 248 can be pre-heated, for example, to about 300° C, such that the processing of active layer 224 begins at the higher temperature, which reduces processing time and saves energy.

Heating active layer 224 using reactor system 240 increases the diffusion rate and solubility of active layer 224. Thus, a shallow doped region may be created in active layer 224. Doping the active layer includes scanning active layer 224 to a process temperature, for example, from between about 500° C. to about 1400° C., in an environment of a doping compound, such as boron, phosphorus, nitrogen, arsenic, B₂H₆, PH₃, N₂O, NO, AsH₃, and NH₃. The concentration of the compound may range from about 0.1% to about 100% relative to a carrier gas, such as H₂, N₂ and O₂ or a non-reactive gas, such as argon or helium. Higher concentrations of the compound can speed up the doping process and/or increase the dopant concentration within the active layer.

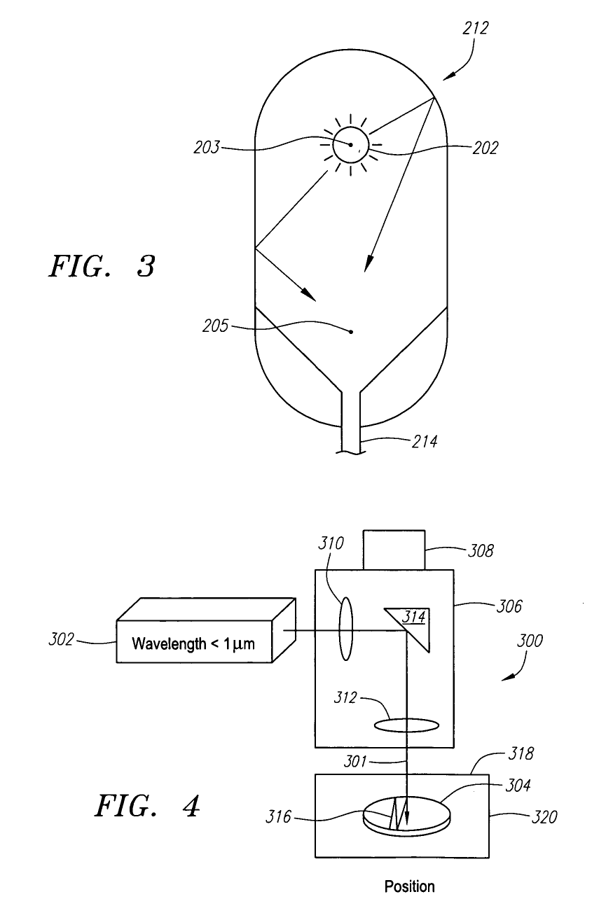

FIG. 4 is a simplified illustration of yet another embodiment of the present invention. In this embodiment, scanner assembly 300 includes a high intensity pulse or continuous wave laser 302 to provide rapid thermal processing of semiconductor wafer 304. Scanner assembly 300 also includes a laser energy focusing assembly 306 and an actuator 308. The components of scanning assembly 300 may be enclosed in a single housing, which is mountable on to a process chamber 320 in a manner similar to the embodiments described above in FIG. 2A.

Laser focusing assembly 306 includes a first focusing lens 310, a second focusing lens 312, and mirror 314. Focusing assembly operates in a well-known, conventional manner to focus the laser energy 301 from laser 302 onto wafer 304. The laser energy 301 from laser 302 can have a wavelength of less than 1 μm.

Actuator 308 provides a conventional means for making scanner assembly 300 operable to scan wafer 304. Actuator 308 may be configured to move laser 302 and focusing assembly 306 to provide a back and forth scanning motion across wafer 304, as indicated in FIG. 4 by arrow 316. Alternatively, only mirror 314 may be moved to cause the laser scanning of wafer 304. In yet another alternative embodiment, wafer 304 may be made to move, such that a stationary beam 301 can be made to scan the wafer surface. Actuator 308 may include, but is not limited to, conventional drivers and motion translation mechanisms, such as linear motors, stepper motors, hydraulic drives, and the like, and gears, pulleys, chains, and the like. In one embodiment, scanner assembly 300 is positioned above an optical window 318, which is provided along the scanning length of process chamber 320 to allow the laser energy to enter process chamber 320 and impinge on wafer 304. Window 318 may be made of any material that allows for the transmission of laser energy 301; for example, transparent quartz. Window 318 may have a thickness of between about 1 and about 5 mm and a diameter that is at least as great as or greater than wafer 304.

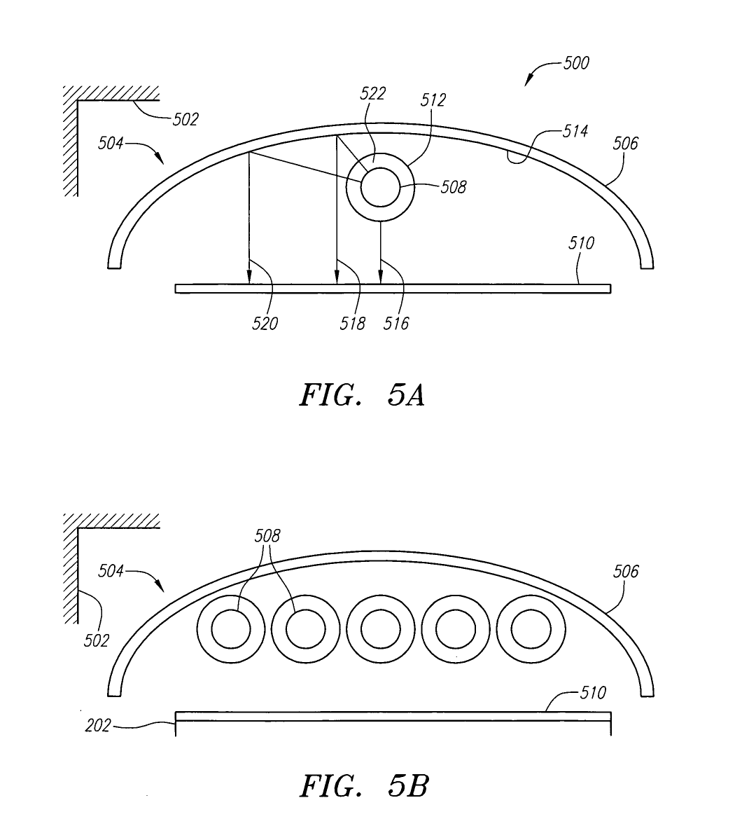

FIG. 5A is a simplified illustration of an embodiment of a reactor system 500 in accordance with the principles of the present invention. In this embodiment, reactor system 500 includes a process chamber 502 and a reflector assembly 504. Reflector assembly 504 may include a reflector 506 and a radiation energy source 508. Reflector assembly 504 may be positioned within process chamber 502 proximate to a wafer 510, such that in operation, reflector assembly 504 can be made to adequately process wafer 510.

In one embodiment, radiation energy source 508 can be a high-intensity lamp of the type conventionally used in lamp heating operations. In this embodiment, radiation energy source 508 is a filament-less lamp, such as a Xe arc lamp (hereinafter “lamp 508”). Lamp 508 can be any suitably shaped lamp, for example, a tube shaped lamp that has a length at least as long as the diameter of wafer 510. In one embodiment, lamp 508 can be surrounded by a flow tube 512. Flow tube 512 can contain a cooling fluid 522, for example, deionized water. Cooling fluid 522 is used to keep lamp 508 from overheating during operation. For example, cooling fluid can keep the temperature of lamp 508 under 100° C. to keep any quartz components of lamp 508 from melting. In another embodiment, cooling fluid 522 can be mixed with a non-conductive die. The non-conductive die can act as a filter to keep only certain wavelengths from emanating from lamp 508 through flow tube 512.

FIG. 5B is a simplified illustration of an alternative embodiment, in which a plurality of lamps 508 are disposed proximate to reflector 506. It should be understood that any number of lamps 508 can be used to achieve the desired heating levels required of a specific process.

Referring again to FIG. 5A, reflector assembly 504 is in operational arrangement with wafer 510. Reflector 506 includes an inner surface 514, which can be highly reflective of certain wavelengths and absorptive or non-reflective of others. In one embodiment, inner surface 514 can be coated with a material, which has the reflecting/absorbing characteristic. For example, inner surface 514 may be coated with gold or silver, where the silver is further coated with a protection coating, such as SiN or any transparent coating, which prohibits oxidation of the silver. The coating efficiently reflects wavelengths of less than 900 nm, to produce an average wavelength of between about 900 nm and about 200 nm. In another embodiment, inner surface is highly reflective across the full spectra of ultra violet (UV), infrared (IR) and visible wavelengths.

Reflector 506 may be formed into any suitable geometric shape. For example, reflector 506 may be flat, spherical, elliptical or parabolic. The light energy from lamp 508 can be focused at the center or focal point of reflector 506 to be directed toward wafer 510. The radiation emitted from lamp 508 and reflected from inner surface 514 of reflector 506 impinges on wafer 510, as simply and representatively illustrated by rays 516, 518 and 520, to provide a uniform temperature distribution across the surface of wafer 510, which heats the active layer 224 of the wafer (as described above in reference to FIG. 2D).

The temperature to which active layer 224 is heated is a function of the relationship between the power supplied to lamp 508 and the length of time which the radiation energy is allowed to impinge on wafer 510.

In another embodiment, after wafer 510 is exposed to the flash of lamp 508, the lamp power can be maintained at a second power level, for example, between about 1000 watts to about 500 kwatts. Wafer 510 can be exposed to the second power level for any time duration that may be necessary to complete the processing of wafer 510. In one example, the continuous exposure can last from between about 0.05 seconds and about 3600 seconds. The continuous exposure can heat the bulk of wafer 510 in addition to heating the active layer during the flash anneal.

Wafer 510 can be pre-heated, for example, to about 300° C,. such that the processing of active layer 224 begins at the higher temperature, which reduces processing time and saves energy.

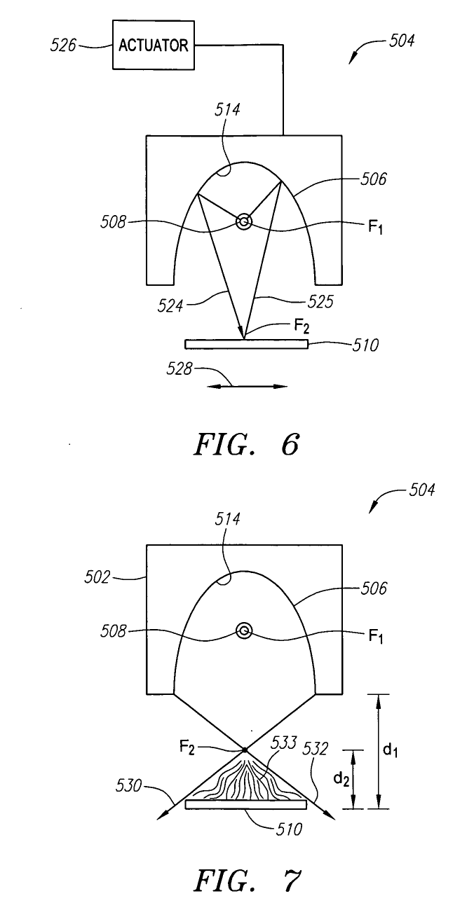

FIG. 6 is a simplified illustration of an alternative embodiment of reflector assembly 504. In this alternative embodiment, reflector 506 may be formed into an ellipse, which has two focal points F₁ and F₂. Lamp 508 can be positioned at focal point F₁, such that the energy is reflected from inner surface 514, exemplified by rays 524 and 525, and focused at the second focal point F₂. Wafer 510 can be positioned at focal point F₂, such that the energy can be used to process wafer 510.

In this embodiment, the entire wafer surface can be subjected to the energy focused at F₂, by moving wafer 510 relative to focal point F₂. For example, actuator 526 can be used to provide a conventional means for causing reflector assembly 504 to scan over wafer 510. Actuator 526 may be configured to move either wafer 510 or reflector assembly 504 to provide a back and forth scanning motion, as indicated by arrow 528, across wafer 510.

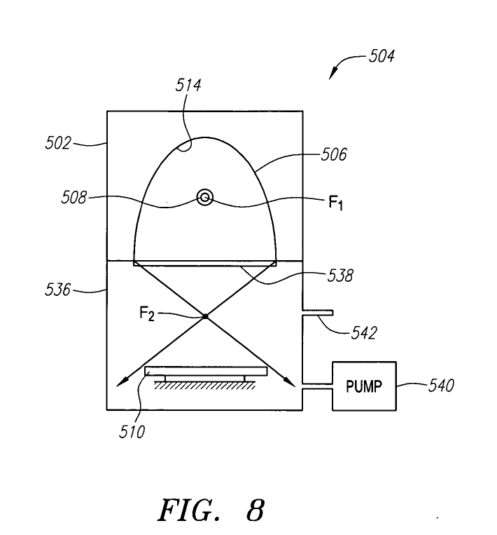

FIG. 7 is a simplified illustration of another embodiment of reflector assembly 504 in accordance with the present invention. In this embodiment, reflector 506 is formed into an ellipse, with two focal points F₁ and F₂. Lamp 508 is positioned at focal point F₁, such that the energy is reflected from inner surface 514 and focused at focal point F₂. In this embodiment, wafer 510 is set back a distance d₁ from reflector assembly 504 and/or a distance d₂ from focal point F₂. Distances d₁ and d₂ are selected such that wafer 510 is fully engulfed within a beam 533 emanating from focal point F₂. Beam 533, outlined by rays 530 and 532, covers the entire surface area of wafer 510, such that the entire surface of wafer 510 is subjected simultaneously to substantially all of the reflected energy from lamp 508 to process wafer 510.

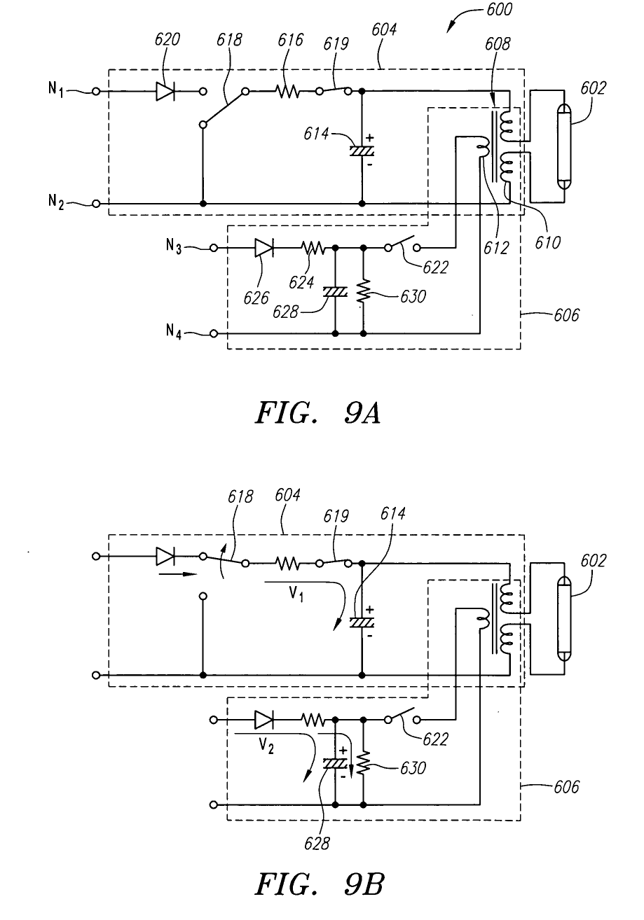

FIG. 8 is a simplified illustration of yet another embodiment of reflector assembly 504 in accordance with the present invention. In this embodiment, process chamber 502 including reflector assembly 504 may be mounted external to a second process chamber 536. Reflector assembly 504 can be positioned above an optical window 538, which is provided between chambers 502 and 536 to allow the radiation energy emitted from lamp 508 to enter second process chamber 536 and impinge on wafer 510. Optical window 538 may be made of any material that allows for the transmission of the radiation energy, for example, quartz. Window 538 may have a thickness of between about 1 and about 5 mm and a diameter that is at least as great as or greater than wafer 510.

Second process chamber 536 can be pulled to vacuum, for example, using a pump 540. Second chamber 536 can also be filled through inlet 542 with a non-oxygen gas, such as N₂. During the processing of wafer 510, the vacuum or non-oxygen environment ensures that the transmission of ultra-violet (UV) wavelengths from lamp 508 can reach wafer 510.

Although second process chamber 536 with quartz window 538 has been illustrated using the embodiment of reflector assembly 504 of FIG. 7, the second process chamber 536 and quartz window 538 can be used with all of the embodiments of reflector assembly 504 described herein. It should also be understood that chambers 502 and 536 may be a single chamber.

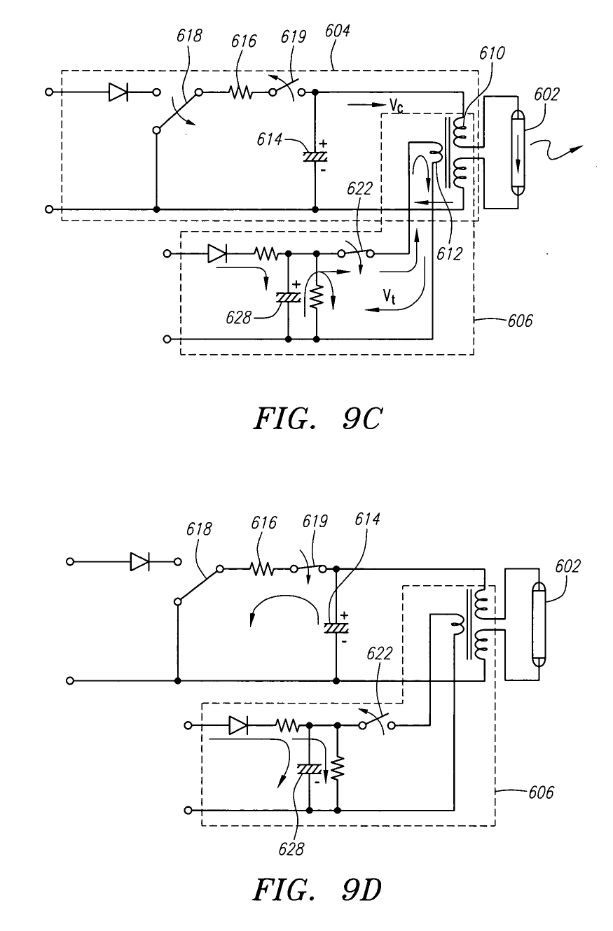

FIGS. 9A-9D are simplified circuit diagrams of a power supply 600 for a lamp 602 in accordance with an embodiment of the present invention. As shown in FIG. 9A, power supply 600 includes a main circuit 604 and an ignition circuit 606. In one embodiment, main circuit 604 includes an ignition transformer 608 whose primary winding 610 can be supplied with a voltage V₁, and whose secondary winding 612 ignites lamp 602 with the stepped-up value of voltage V₁. In this embodiment, a capacitor 614 is provided in parallel to a series connection of primary winding 610 and a controllable switch 618. Capacitor 614 can be of any desired capacitance, for example, between about 10 μF and 100 F. Switch 618 can be, for example, any suitable manual switch, electromagnetic relay or solid state device.

In this embodiment, capacitor 614 can be connected in parallel with a resistor 616 and a diode 620 provided in series with resistor 616. When charging capacitor 614, resistor 616 acts as a current limiter and/or a dummy load. Capacitor 614 is charged when supply voltage V₁ is activated across nodes N₁ and N₂. Voltage V₁ can be an AC voltage supplied via a direct line or a transformer output. Voltage V₁ can be adjustable and may range from between about 200 VAC and 5000 VAC.

Ignition circuit 606 supplies the ignition energy with the aid of a pulse switch 622. For this purpose, ignition circuit 606 is provided with secondary winding 612 of ignition transformer 608. A resistor 624, in series with diode 626, is provided in series with secondary winding 612 and pulse switch 622. A capacitor 628, disposed in parallel to a shunt resistor 630, is in series connection to secondary winding 612. Capacitor 628 can be of any desired capacitance, for example, between about 0.1 μF and 100 μF. Capacitor 628 can be charged by a voltage V₂, placed across nodes N₃ and N₄. Voltage V₂ can be an AC voltage supplied via a direct line or a transformer output. Voltage V₂ can be adjustable and may range from between about 200 VAC and 1000 VAC. Alternatively, for simplicity, nodes N₁ and N₂ can be electrically coupled to nodes N₃ and N₄ so as to share the same power source.

FIG. 9B shows an embodiment of primary circuit 604 and ignition circuit 606 where switches 618 and 619 are closed to allow supply voltage V₁ to be applied between nodes N₁ and N₂, to begin the charging via resistor 616 of capacitor 614. At the same time, capacitor 628 of ignition circuit 606 is charged via resistor 624 with voltage V₂ applied between nodes N₃ and N₄.

FIG. 9C shows an embodiment, such that when capacitor 614 is charged to a desired capacity, switch 618 can be opened and switch 619 can be opened, thus removing the effect of supply voltage V₁ on capacitor 614 and allowing a voltage V_{c} to be supplied from capacitor 614 across primary windings 610. Impulse switch 622 can be closed to allow capacitor 628 to discharge, such that a voltage Vₜ is supplied across secondary windings 612. According to the transmission ratio of ignition transformer 608, a current flux generates a stepped-up voltage in primary windings 610 that is high enough to energize lamp 602.

As shown in FIG. 9D, once lamp 602 has been energized as desired, switch 622 can be released (i.e. opened) and switch 619 can be closed to allow capacitor 614 to continue to discharge via the dummy load supplied through resistor 616. In this configuration, capacitor 628 of ignition circuit 606 begins to be re-charged once switch 622 is opened. Primary circuit 604 can be re-charged with the closing of switch 618.

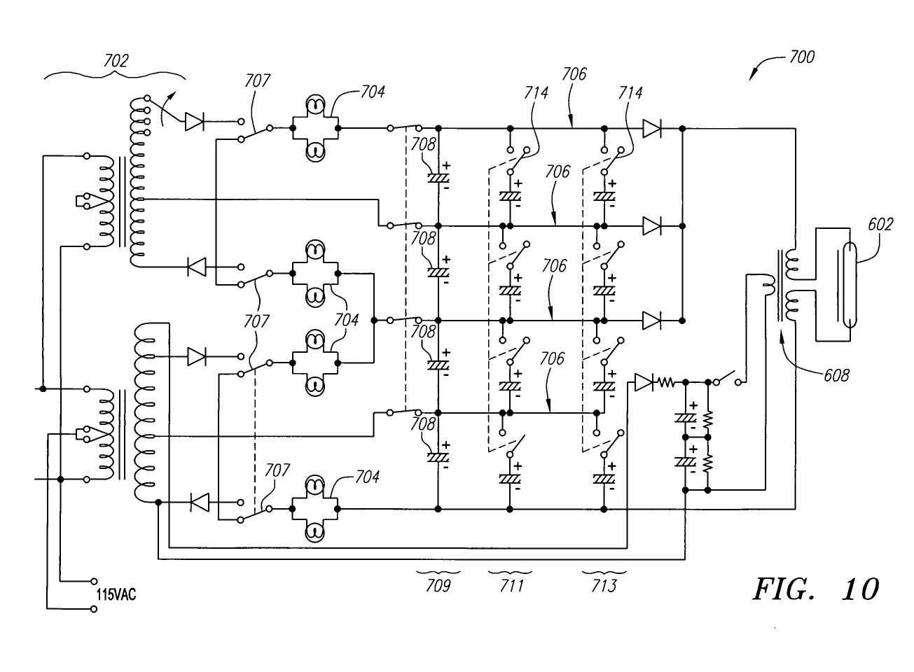

FIG. 10 is an embodiment of a power supply circuit 700 configured using the principles described in reference to FIGS. 9A-9D. This embodiment illustrates the versatility of power supply circuit 700. As best understood with reference to FIG. 10, capacitors 708 from a plurality of primary circuits 706 can be stacked together to be used in conjunction with one another to increase the charge storing capacity of power supply 700. The stacked capacitors 708 form a first rack 709. Each primary circuit 706 can be connected together upon the closing of switches or relays 707. As the capacity of the voltage is increased a plurality of capacitor racks, such as second rack 711 and third rack 713 can be connected in parallel with first rack 709 via a set of switches 714. The racks 709, 711, and 713 can be used together to vary the capacitance and thus the power level supplied to lamp 602.

FIG. 10 illustrates additional versatility of power supply 700. For example, AC power source 702 can be configured to provide a variable voltage, ranging for example between about 200 VAC and about 5000 VAC. In addition, resistor 704 of the primary circuit can be a halogen lamp or similar device, which can be used to dissipate heat energy and also provide a visual indication that the capacitor in the circuit is being charged or discharged.

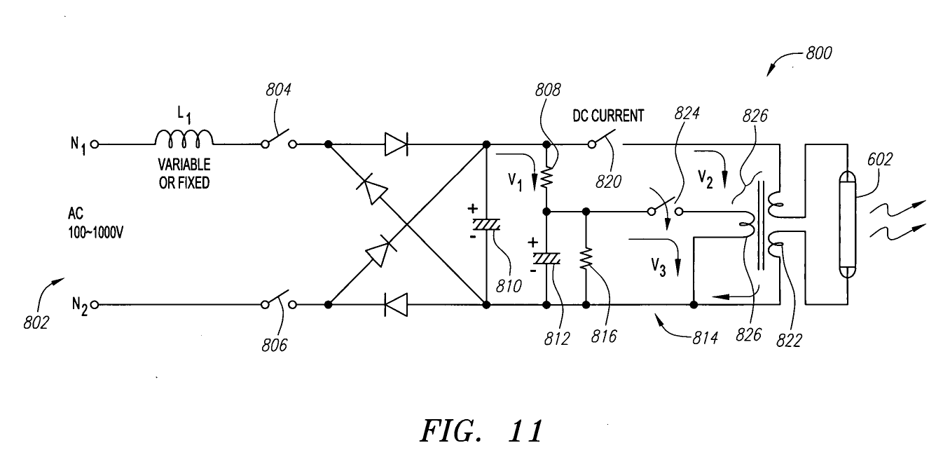

FIG. 11 is an embodiment of a power supply circuit 800 using the principles described in reference to FIGS. 9A-9D with the additional ability to allow a continuous powering of lamp 602. Accordingly, power supply circuit 800 can provide a flash exposure to the radiation energy of lamp 602 followed by a continuous component of exposure to the radiation energy of lamp 602. Power supply circuit 800 includes power circuit 802, where switches 804 and 806 when closed allow an AC supply voltage V₁ to be applied between nodes N₁ and N₂, to begin the charging via resistor 808 of capacitor 810. At the same time, capacitor 812 of ignition circuit 814 is charged via resistor 816. A set of diodes 818 are provided to convert the AC voltage supply to a DC voltage supply. When capacitors 810 and 812 are charged to desired capacities, switch 820 is closed allowing a voltage V₂ to be supplied from capacitor 810 across primary windings 822. Impulse switch 824 can be closed to allow capacitor 812 to discharge, such that a voltage V₃ is supplied across secondary windings 826. According to the transmission ratio of ignition transformer 826, a current flux generates a stepped-up voltage in primary windings 822 that is high enough to energize lamp 602. Once ignition switch 824 is released, voltage V₂ remains across the primary windings to allow lamp 602 to remain energized and, thus producing a radiation energy output. In this manner, discharge time can be controlled.

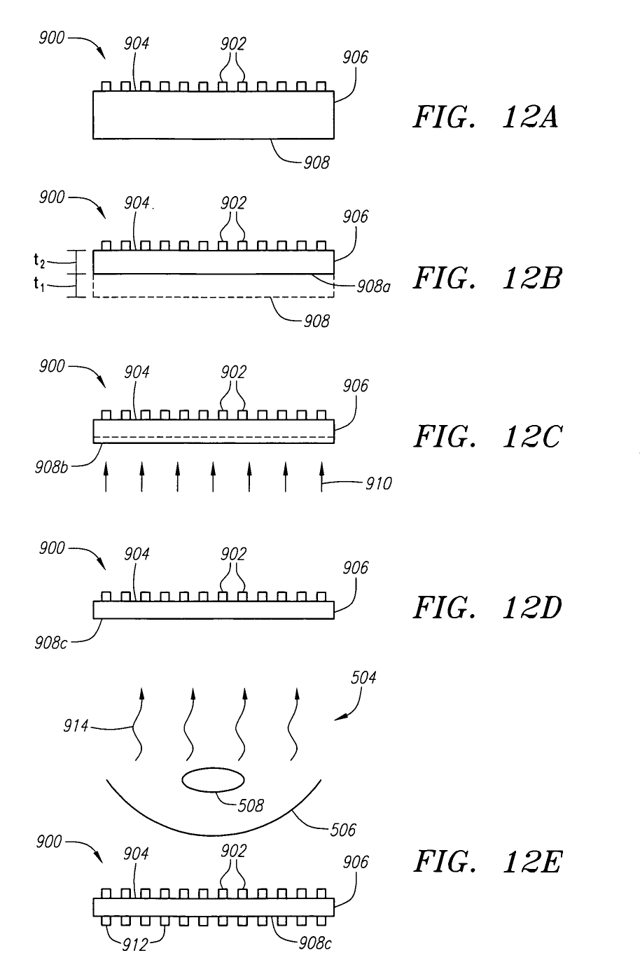

FIGS. 12A-12D are simplified illustrations of the formation of a vertical planar semiconductor device in accordance with an embodiment of the present invention. As shown in FIG. 12A, a vertical semiconductor device 900 is provided which includes devices 902, such as transistors, diodes, and the like, formed in the active layer on a first side 904 of semiconductor substrate 906.

Referring now to FIG. 12B, if desired, substrate 906 can have material removed a depth t, from second side 908 so that the substrate can have a desired thickness t₂. Thickness t₂ can range from between about 50 μm and 500 μm, for example, 300 μm or less, depending on the application. The material may be removed using any well known removal technique, such as grinding, polishing and the like. The newly exposed back side surface 908a can then be subjected to further processing as described below.

As illustrated in FIG. 12C, after removing material from substrate 906, second side 908a can be doped using well known ion implantation techniques, which forms a doped region on second side 908b.

In order to electrically activate the active layer of second side 908b, doped second side 908b must be annealed at annealing temperatures of between about 500° C and 1400° C. However, since in this embodiment semiconductor devices 902 are formed on first side 904 of substrate 906, the first side 904 should not be heated to temperatures that would impair the structural or operational integrity of materials that constitute the semiconductor devices 902. For example, metallization layers, which are typically fabricated using aluminum, cannot be heated to temperatures which exceed the melting temperature of aluminum.

As shown in FIG. 12D, to avoid overheating the first side 904 and ultimately the semiconductor devices 902, second side 908b is subjected to a flash of radiation energy 914 to heat and, therefore, electrically activate the ions implanted in the active layer of substrate 906.

FIG. 12D shows a simplified illustration of reflector assembly 504 as described in earlier embodiments (e.g., FIGS. 5A and 5B). Reflector assembly 504 may include a reflector 506 and a radiation energy source 508. As described in embodiments above, reflector assembly 504 may be positioned within a process chamber proximate to substrate 906, such that in operation, reflector assembly 504 can be made to adequately process second side 908b to form processed second side 908c.

In one embodiment, radiation energy source 508 can be a high-intensity lamp of the type conventionally used in lamp heating operations. For example, radiation energy source 508 is a filament-less lamp, such as a Xe arc lamp. Substrate 906 is subjected to the flash of radiation energy 914 (i.e., flash anneal process) in the manner described above with regard to the various embodiments.

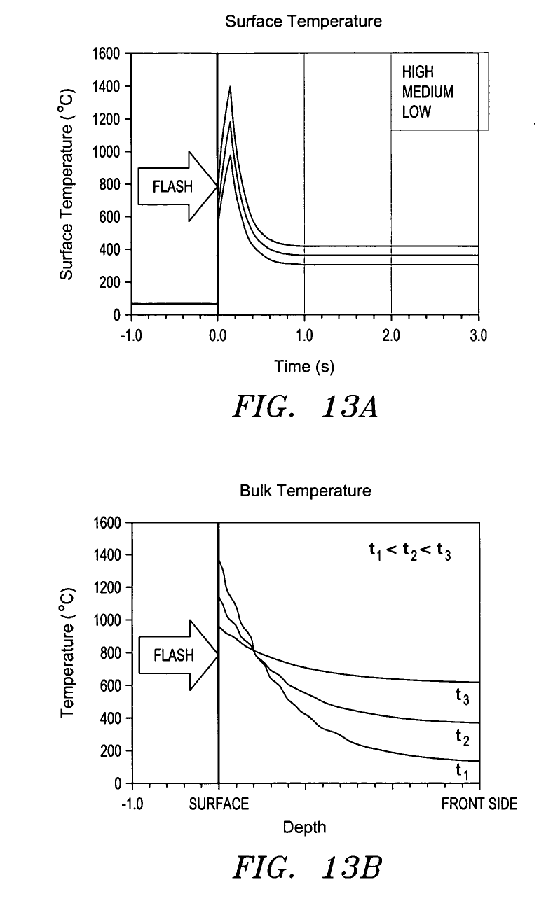

The temperature to which the active layer of second side 908b is heated is a function of the relationship between the power supplied to radiation energy source 508 and the length of time which the radiation energy is allowed to impinge on wafer 510. As shown in FIG. 13A, in one embodiment, the temperature of the active layer of second side 908b may be raised to an annealing temperature in the range from between about 500° C. (low) to about 1400° C. (high). To achieve these temperatures, the wafer is exposed to a flash in accordance with the present invention, which provides light energy suddenly or substantially instantaneously, for example, for a duration of time between about 1 nanosecond and about 10 seconds, for example, less than 1 second. The power level can range from between about 0.5 J/cm² and about 100 J/cm².

Beneficially, the flash anneal process described above substantially heats only the active layer of second side 908b to the annealing temperature, thus protecting devices 902 formed on first side 904. As illustrated in the graph shown in FIG. 13B, the bulk temperature of the wafer diminishes as a function of the increase in depth towards the second side or opposing surface. Moreover, the more instantaneous the pulse of energy generated by the flash, the less impact to the opposite surface. Thus, although some heat may permeate from the back side through the remainder of the bulk semiconductor substrate, the amount of heat energy which reaches first side 904 can be maintained at a temperature low enough to avoid causing the loss of structural or operational integrity of devices 902.

Although FIG. 12D illustrates one exemplary embodiment of reflector assembly 504, it should be understood that the formation of the vertical planar semiconductor device 900 is not limited to the use of any one exemplary embodiment described herein or its equivalent.

As shown in FIG. 12E, after activating the active layer of the back side, second side 908c can be processed in a well known manner to create semiconductor devices 912 thereon.

In an alternative embodiment, the active layer of first side 904 (FIG. 12A) can be electrically activated in the same manner as discussed above with regard to the active layer of second side 908 of substrate 906 prior to the formation of semiconductor devices 902. Thus, it should be understood that the flash anneal process described can be used to process both the front side and back side semiconductor devices.

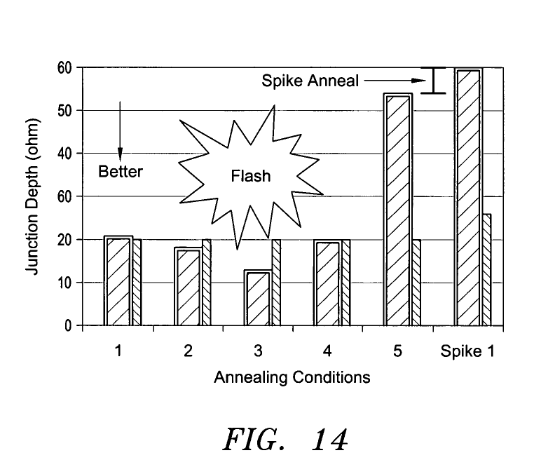

FIG. 14 illustrates the results of a USJ implant anneal conducted with an implant species of ⁴⁹BF₂+, implant energy of 3 keV and an implant dose of 1.0˜1.5 nm using the principles of the present invention. As shown in the graph of FIG. 14, under five different annealing conditions using flash annealing, the junction depths remained below 20 nm, while sheet resistance also remained relatively low. For comparison, the same implant was conducted using a 1000° C. anneal, which heats the entire bulk wafer, and is sometimes referred to as a “spike” anneal process. The result of the spike anneal process was a junction depth of about 60 nm and a sheet resistance of about 500 ohm/sq.

Having thus described embodiments of the present invention, persons skilled in the art will recognize that changes may be made in form and detail without departing from the spirit and scope of the invention. Thus the invention is limited only by the following claims.

1. A method for forming an electronic device, comprising:
providing a substrate having a front side and a back side, said front side having a layer disposed thereon including a material having a low melting point;
implanting an impurity into said back side of said substrate;
flashing said back side of said substrate with radiation energy which impinges on a surface of said back side of said substrate for a substantially instantaneous time to heat an active layer of said substrate to an annealing temperature.

2. The method of claim 1, wherein said radiation energy is derived from a radiation energy source comprising a high-intensity lamp.

3. The method of claim 2, wherein said high-intensity lamp comprises a Xe arc lamp.

4. The method of claim 1, wherein said low melting point is in the range of between 100° C. and 1400° C.

5. The method of claim 1, wherein said radiation energy comprises an average power of between about 0.5 J/cm² and about 100 J/cm².

6. The method of claim 1, wherein said active layer comprises a portion of said substrate between 10 nm and about 1 mm below a surface of said substrate.

7. The method of claim 1, wherein said annealing temperature is between about 500° C. and 1400° C.

8. The method of claim 1, wherein said substantially instantaneous time is between about 1 nanosecond and about 10 seconds.

9. The method of claim 1, wherein said implanting an impurity into said back side of said substrate comprises accelerating dopant ions to between 20 keV and 100 keV into said back side surface.

10. The method of claim 1, wherein said implanting an impurity into said back side of said substrate comprises thermally diffusing a dopant in a gaseous ambient.

11. A method for forming an electronic device, comprising:
providing a substrate having a front side and a back side, said front side having a first semiconductor device disposed thereon;
removing substrate material from said back side of said substrate;
implanting an impurity into said back side of said substrate;
flashing said back side of said substrate with radiation energy which impinges on a surface of said back side of said substrate for a substantially instantaneous time to heat an active layer of said substrate to an annealing temperature; and
forming a second semiconductor device on said back side of said substrate.

12. An apparatus for forming an electronic device, comprising:
means for flashing a first surface of a substrate with radiation energy which impinges on said first surface for a substantially instantaneous time to heat an active layer of said substrate to an annealing temperature, said substrate having a second surface having a semiconductor device formed thereon.

13. The apparatus of claim 12, wherein said means for flashing comprises:
at least one radiation energy source; and
a reflector assembly substantially surrounding said at least one radiation energy source, said reflector assembly including a reflective surface for focusing radiation energy from said radiation energy source to impinge on said first surface.

14. The apparatus of claim 12, wherein said substantially instantaneous time comprises between about 1 nanosecond and about 10 seconds.

15. The apparatus of claim 12, wherein said annealing temperature comprises between about 500° C. and about 1400° C.

16. The apparatus of claim 13, wherein said radiation energy source comprises a Xe arc lamp.

17. The apparatus of claim 12, wherein said active layer comprises a portion of said substrate which extends from between said first surface to about 1 mm below said first surface of said substrate.

18. The apparatus of claim 12, wherein said radiation energy comprises an average power of between about 0.5 J/cm² and about 100 J/cm².

19. The apparatus of claim 12, wherein said active layer comprises a portion of said substrate from between said first surface and a depth below said first surface in the range of between about 10 nm and about 1 mm.
